(19) United States
(12) Patent Application Publication
(10) Pub. No.: US 2015/0245504 A1
(43) Pub. Date: Aug. 27, 2015

(54) ELECTRONIC APPARATUS

(71) Applicant: InnoLux Corporation, Miao-Li County (TW)

(72) Inventors: Bo ZHANG, Miao-Li County (TW); Ching-I LO, Miao-Li County (TW)

(21) Appl. No.: 14/631,368

(22) Filed: Feb. 25, 2015

(30) Foreign Application Priority Data
Feb. 25, 2014 (TW) 103106289

(51) Int. Cl. H05K 5/00; H05K 5/04

(52) U.S. Cl. CPC H05K 5/0026; H05K 5/04; H05K 5/0017

(57) ABSTRACT

An electronic apparatus includes a metallic housing, a circuit board and an adhesive. The metallic housing includes a first engaging structure. The circuit board includes a second engaging structure, which is coupled to the first engaging structure. The adhesive is disposed between the first and second engaging structures to connect the metallic housing and the circuit board. The manufacturing efficiency of the electronic apparatus can be enhanced by the adhesive connecting the metallic housing and the circuit board.

### CROSS REFERENCE TO RELATED APPLICATIONS

This Non-provisional application claims priority under 35 U.S.C. §119(a) on Patent Application No(s). 103106289 filed in Taiwan, Republic of China on Feb. 25, 2014, the entire contents of which are hereby incorporated by reference.

### BACKGROUND OF THE INVENTION

1. Field of Invention

The invention relates to an electronic apparatus and, in particular, to an electronic apparatus including a circuit board.

2. Related Art

The circuit board, such as a printed circuit board (PCB), is an important electronic component carrying many electronic elements to provide the electronic apparatus with a particular function.

In the conventional electronic apparatus, the circuit board is usually connected to a metallic housing, especially by screwing, for being fixed and configured with a grounding effect. However, since the size of the screw is too small, operators are required for making the assembly, so that the assembly efficiency of the electronic apparatus is lowered down a lot and the manufacturing cost is increased.

Therefore, it is an important subject to provide an electronic apparatus which can be enhanced in the assembly efficiency and decreased in the cost by an innovative mechanism design.

### SUMMARY OF THE INVENTION

In view of the foregoing subject, an objective of the invention is to provide an electronic apparatus which can be enhanced in the assembly efficiency and decreased in the cost by an innovative mechanism design.

To achieve the above objective, an electronic apparatus according to the invention includes a metallic housing, a circuit board and an adhesive. The metallic housing includes a first engaging structure. The circuit board includes a second engaging structure, which is coupled to the first engaging structure. The adhesive is disposed between the first and second engaging structures to connect the metallic housing and the circuit board.

In one embodiment, the material of the metallic housing includes metal or alloy.

In one embodiment, the metallic housing includes a recess to form the first engaging structure, the circuit board includes a protrusion to form the second engaging structure, and the adhesive is disposed in the gap between the recess and the protrusion during the assembly.

In one embodiment, the metallic housing includes a protrusion to form the first engaging structure, the circuit board includes a recess to form the second engaging structure, and the adhesive is disposed in the gap between the recess and the protrusion during the assembly.

In one embodiment, the metallic housing includes a protrusion to form the first engaging structure, the circuit board includes an inner annular surface to form a through hole to form the second engaging structure, and the protrusion passes through the through hole and the adhesive is disposed in the gap between the protrusion and the inner annular surface during the assembly.

In one embodiment, the adhesive is a conductive adhesive.

In one embodiment, the circuit board has a grounding area, and the grounding area is connected to the metallic housing through a conductive element.

In one embodiment, the conductive element includes a conductive tape and an insulating tape, the insulating tape is attached to the conductive tape so that a grounding portion of the conductive tape is exposed, and the grounding portion is coupled to the grounding area of the circuit board.

In one embodiment, the electronic apparatus is a flat display apparatus.

As mentioned above, an electronic apparatus of the invention includes a metallic housing, a circuit board and an adhesive. The metallic housing includes a first engaging structure. The circuit board includes a second engaging structure, which is coupled to the first engaging structure. The adhesive is disposed between the first and second engaging structures to connect the metallic housing and the circuit board. Thereby, the screw is not required for fastening the metallic housing and the circuit board so that the assembly efficiency of the electronic apparatus can be enhanced and the labor cost can be reduced.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram of an electronic apparatus of an embodiment of the invention;

FIG. 2 is a schematic sectional diagram showing a connection area A of the circuit board and metallic housing of the electronic apparatus in FIG. 1;

FIG. 3 is a schematic diagram of a variation of the first and second engaging structures of an embodiment of the invention;

FIG. 4 is a schematic diagram of an electronic apparatus of another embodiment of the invention; and

FIG. 5 is a schematic diagram of a conductive element of an embodiment of the invention.

### DETAILED DESCRIPTION OF THE INVENTION

The present invention will be apparent from the following detailed description, which proceeds with reference to the accompanying drawings, wherein the same references relate to the same elements.

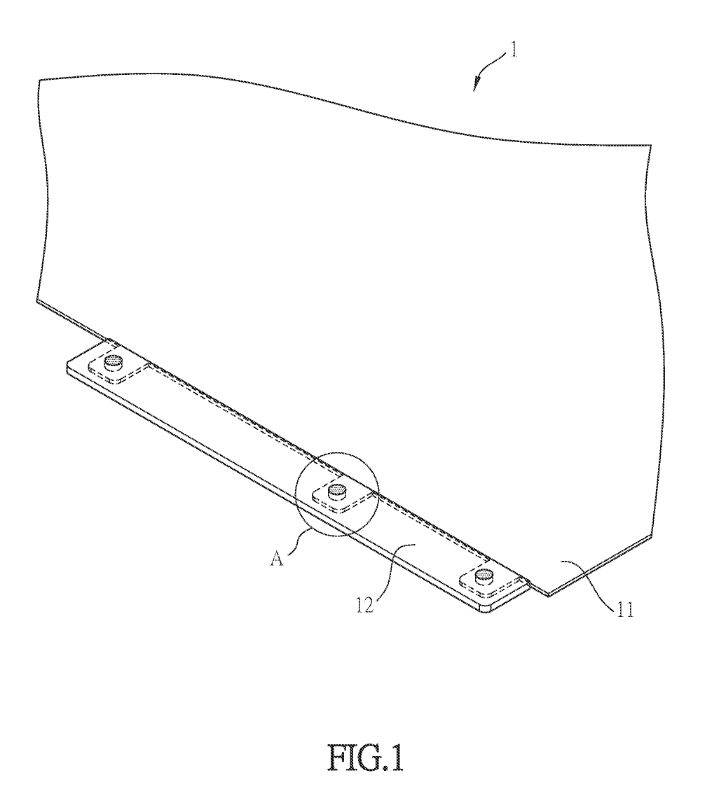

FIG. 1 is a schematic diagram of an electronic apparatus 1 of an embodiment of the invention. As shown in FIG. 1, the electronic apparatus 1 includes a metallic housing 11 and a circuit board 12. The type of the electronic apparatus 1 is not limited in this invention, and the electronic apparatus 1 can be a lighting apparatus or a display apparatus for example. The display apparatus is a flat display apparatus for example. Besides, according to the type, the electronic apparatus 1 can further include other elements. For example, when being a flat display apparatus, the electronic apparatus 1 further includes a display panel, which can be a self-luminous display panel or a non-self-luminous display panel, and the electronic apparatus 1 can further include a backlight module in the non-self-luminous case. Moreover, the position and type of the metallic housing 11 are also not limited in this invention, and the metallic housing 11 can be an outside housing or a housing inside the apparatus for example. The circuit board 12 is a system circuit board or a circuit board for achieving a particular function for example, and can be a scan driving circuit board or data driving circuit board in the display apparatus. To be noted, the above description is just for the illustrative purpose but not for limiting the scope of the invention.

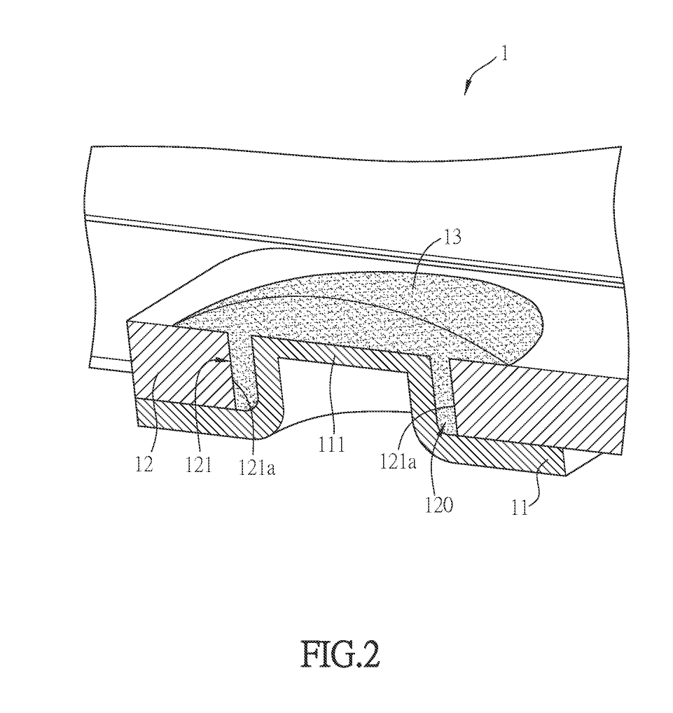

The circuit board 12 is connected to the metallic housing 11. FIG. 2 is a schematic sectional diagram showing a connection area A of the circuit board 12 and metallic housing 11 of the electronic apparatus 1 in FIG. 1. As shown in FIGS. 1 and 2, the metallic housing 11 includes a first engaging structure 111, which includes a recess, a protrusion, a through hole or their any combination for example. Herein, the first engaging structure 111 is a protrusion as an example, and the protrusion is disposed perpendicularly. The material of the metallic housing 11 includes metal or alloy. The metallic housing 11 can be made completely by conductive material or partially by conductive material, and especially the portion of the metallic housing 11 connected to the circuit board 12 is made by conductive material.

The circuit board 12 includes a second engaging structure 121, which is coupled to the first engaging structure 111. The second engaging structure 121 includes a recess, a protrusion, a through hole or their any combination. Herein, the second engaging structure 121 is a through hole for example, and the through hole is formed and encircled by an inner annular surface 121a. Moreover, the first engaging structure 111 embodied as a protrusion passes through the second engaging structure 121 (through hole). Besides, for the assembly convenience and the consideration to the process tolerance, a gap 120 will exist between the first engaging structure 111 (protrusion) and the inner annular surface 121a when they are engaged with each other.

The electronic apparatus 1 further includes an adhesive 13, which is disposed between the first and second engaging structures 111 and 121 and partially disposed in the gap 120 to connect the metallic housing 11 and the circuit board 12. In this embodiment, the adhesive is a connecting glue for example. In other embodiments, it also can be soldering tin or other connecting glues. In one embodiment, the adhesive 13 can enter the region between the first and second engaging structures 111 and 121 by a dispensing manner so that the metallic housing 11 and the circuit board 12 can be tightly connected to each other. For example (as shown in FIGS. 1 and 2), the metallic housing 11 of this embodiment includes three first engaging structures 111 while the circuit board 12 includes three second engaging structures 121, the second engaging structures 121 and the first engaging structures 111 are disposed correspondingly and coupled to each other, and the metallic housing 11 and the circuit board 12 can be connected to each other by the adhesive 13 disposed between the second engaging structures 121 and the first engaging structures 111.

In another embodiment, the metallic housing can include a recess to form the first engaging structure, the circuit board can include a protrusion to form the second engaging structure, and the adhesive is disposed in the gap between the recess and the protrusion during the assembly. In another embodiment, the metallic housing can include a protrusion to form the first engaging structure, the circuit board can include a recess to form the second engaging structure, and the adhesive is disposed in the gap between the recess and the protrusion during the assembly.

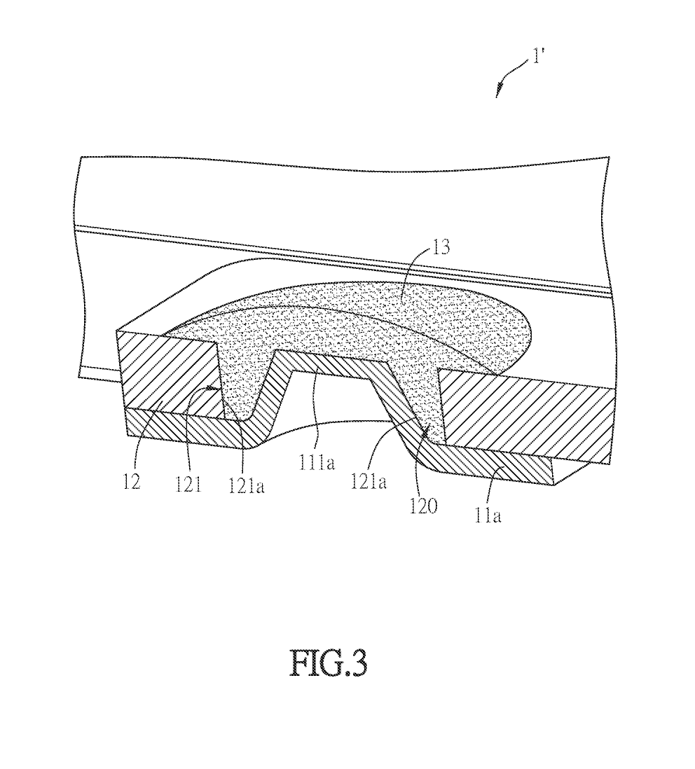

In other embodiments, the first and second engaging structures 111 and 121 can have many variations and an example is illustrated as below. As shown in FIG. 3, a first engaging structure 111a of the metallic housing 11a has an inclined angle, so that the gap between the first and second engaging structures 111a and 121 is enlarged to contain more adhesive 13.

The adhesive 13 of this embodiment can be a conductive adhesive, and therefore the circuit board 12 can be configured with a grounding effect by the adhesive 13 connecting the metallic housing 11.

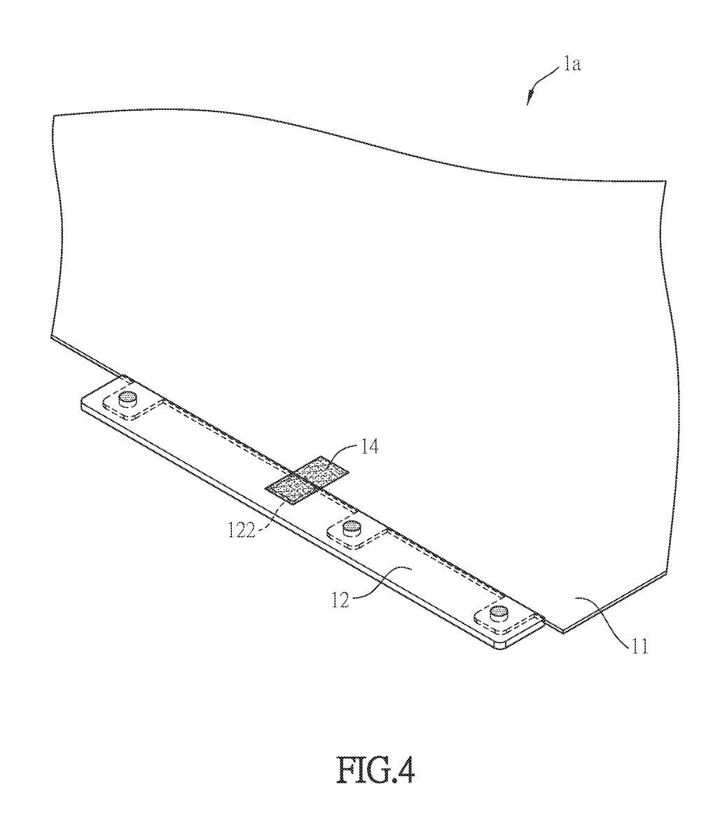

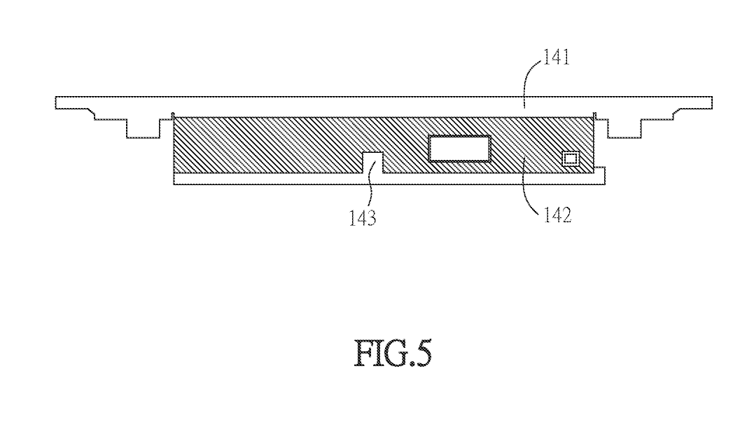

FIG. 4 is a schematic diagram of an electronic apparatus 1a of another embodiment of the invention. As shown in FIG. 4, the adhesive (not shown) of the electronic apparatus 1a is without electric conductivity. In this embodiment, the circuit board 12 further includes a grounding area 122, and the grounding area 122 is connected to the metallic housing 11 through a conductive element 14 so as to be configured with a grounding effect. In this embodiment, the conductive element 14 is an adhesive tape with electric conductivity for example. FIG. 5 is a schematic diagram of the conductive element 14 of an embodiment of the invention. As shown in FIG. 5, the conductive element 14 includes a conductive tape 141 and an insulating tape 142, and the insulating tape 142 is attached to the conductive tape 141 so that a grounding portion 143 of the conductive tape 141 can be exposed. When the conductive element 14 connects the metallic housing 11 and the circuit board 12, the grounding portion 143 of the conductive element 14 is coupled to the grounding area 122 of the circuit board 12 and the grounding effect can be thus achieved.

Summarily, an electronic apparatus of the invention includes a metallic housing, a circuit board and an adhesive. The metallic housing includes a first engaging structure. The circuit board includes a second engaging structure, which is coupled to the first engaging structure. The adhesive is disposed between the first and second engaging structures to connect the metallic housing and the circuit board. Thereby, the screw is not required for fastening the metallic housing and the circuit board so that the assembly efficiency of the electronic apparatus can be enhanced and the labor cost can be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electronic apparatus, comprising:
a metallic housing including a first engaging structure;
a circuit board including a second engaging structure, which is coupled to the first engaging structure; and
an adhesive disposed between the first and second engaging structures to connect the metallic housing and the circuit board.

2. The electronic apparatus as recited in claim 1, wherein the metallic housing includes a recess to form the first engaging structure, the circuit board includes a protrusion to form the second engaging structure, and the adhesive is disposed in the gap between the recess and the protrusion.

3. The electronic apparatus as recited in claim 2, wherein the adhesive is a conductive adhesive.

4. The electronic apparatus as recited in claim 1, wherein the metallic housing includes a protrusion to form the first engaging structure, the circuit board includes a recess to form the second engaging structure, and the adhesive is disposed in the gap between the recess and the protrusion.

5. The electronic apparatus as recited in claim 4, wherein the adhesive is a conductive adhesive.

6. The electronic apparatus as recited in claim 1, wherein the metallic housing includes a protrusion to form the first engaging structure, the circuit board includes an inner annular surface to form a through hole to form the second engaging structure, and the protrusion passes through the through hole and the adhesive is disposed in the gap between the protrusion and the inner annular surface.

7. The electronic apparatus as recited in claim 6, wherein the adhesive is a conductive adhesive.

8. The electronic apparatus as recited in claim 1, wherein the material of the metallic housing includes metal or alloy.

9. The electronic apparatus as recited in claim 1, wherein the circuit board has a grounding area, and the grounding area is connected to the metallic housing through a conductive element.

10. The electronic apparatus as recited in claim 9, wherein the conductive element includes a conductive tape and an insulating tape, the insulating tape is attached to the conductive tape so that a grounding portion of the conductive tape is exposed, and the grounding portion is coupled to the grounding area of the circuit board.

11. The electronic apparatus as recited in claim 1, which is a flat display apparatus.
